(19) United States
(12) Patent Application Publication
(10) Pub. No.: US 2025/0071924 A1
(43) Pub. Date: Feb. 27, 2025

(54) Tall DIMM Structural Retention

(71) Applicant: Intel Corporation, Santa Clara, CA (US)

(72) Inventors: Phil Geng, Washougal, WA (US); David Shia, Portland, OR (US); Xiang Li, Portland, OR (US); George Vergis, Portland, OR (US); Ralph Miele, Hillsboro, OR (US); Sanjoy Saha, Portland, OR (US); Jeffory Smalley, East Olympia, WA (US)

(73) Assignee: Intel Corporation, Santa Clara, CA (US)

(21) Appl. No.: 18/940,819

(22) Filed: Nov. 7, 2024

(51) Int. Cl. H05K 7/14

(52) U.S. Cl. CPC H05K 7/1402

(57) ABSTRACT

Methods and apparatus relating to tall Dual Inline Memory Module (DIMM) structural retention are described. In one embodiment, a Dual In-Line Memory Module (DIMM) retention frame is coupled to a top portion of a tall (e.g., “two unit” or taller) DIMM. A plurality of fasteners physically attach the DIMM retention frame to a Printed Circuit Board (PCB). The DIMM retention frame reduces movement of the tall DIMM. Other embodiments are also claimed and disclosed.

### FIELD OF THE INVENTION

The present disclosure generally relates to the field of electronics. More particularly, an embodiment relates to tall Dual Inline Memory Module (DIMM) structural retention.

### BACKGROUND OF THE INVENTION

Tall Dual Inline Memory Module (DIMM) connectors mounted on a Printed Circuit Board (PCB) generally have high dynamic risk along the lateral DIMM direction.

Some current board level solutions may be provided through DIMM connector component indirectly. These solutions may, however, generate significant tall DIMM lateral movement and high DIMM connector solder joint risks.

Furthermore, some current system level solutions may be provided through chassis top side retention to DIMM top edge. These solutions may, however, be highly dependent on chassis configurations and may not be sufficiently effective.

### BRIEF DESCRIPTION OF DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 shows an example of a tall DIMM, which may be utilized in some embodiments.

FIGS. 2A and 2B, respectively, illustrate a side view of a tall DIMM retention frame and a top view of the tall DIMM retention frame, according to some embodiments.

FIG. 3 illustrates a side view of a full DIMM retention frame with a back plate attached to PCB, according to an embodiment.

FIG. 4 illustrates a side view of a full DIMM retention frame attached to hole mount clips on a motherboard, according to an embodiment.

FIG. 5 illustrates a side view of a full DIMM retention frame attached to soldered surface mount clips or hooks on a motherboard, according to an embodiment.

FIG. 6 shows a side view of a tall DIMM retention frame, according to an embodiment.

FIG. 7 illustrates a top view of a full tall DIMM retention frame constraining DIMM top edge, according to an embodiment.

FIG. 8 illustrates a top view of a partial tall DIMM retention frame, according to an embodiment.

FIG. 9 illustrates a side view of a partial tall DIMM retention frame, according to an embodiment.

FIG. 10 illustrates an exploded view of a portion of the DIMM retention frame mount of FIG. 9, according to an embodiment.

FIG. 11 illustrates a one-piece or full tall DIMM retention frame, according to an embodiment.

FIG. 12 illustrates a side view of a partial DIMM retention frame, according to an embodiment.

FIG. 13 illustrates a block diagram of an embodiment of a computing system, which may be utilized in various embodiments discussed herein.

FIG. 14 illustrates a block diagram of an embodiment of a computing system, which may be utilized in various embodiments discussed herein.

FIG. 15 illustrates various components of a processer in accordance with some embodiments.

### DETAILED DESCRIPTION OF THE INVENTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware (such as logic circuitry or more generally circuitry or circuit), software, firmware, or some combination thereof.

As mentioned above, some tall Dual Inline Memory Module (DIMM) connectors mounted on a Printed Circuit Board (PCB) may generally have high dynamic risk along the lateral DIMM direction. Furthermore, some system level solutions provided through chassis top side retention to DIMM top edge may be highly dependent on chassis configurations and may not be sufficiently effective.

To this end, some embodiments provide solutions for tall DIMM structural retention. An embodiment provides DIMM retention directly to a PCB. Another embodiment provides DIMM retention directly attached to the bottom of a chassis. In one embodiment, a DIMM retention frame is coupled to a top portion of a tall (e.g., “two unit” or taller) DIMM. A plurality of fasteners physically attach the DIMM retention frame to a PCB, to reduce movement of the tall DIMM (e.g., in the lateral or vertical directions).

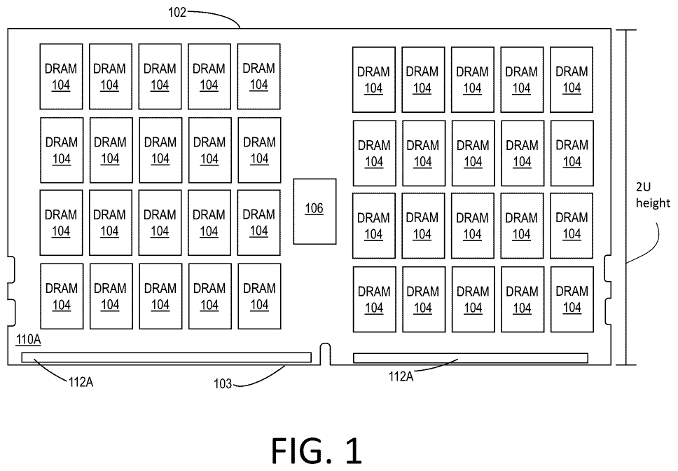

FIG. 1 shows an example of a tall 2U (“two unit”) DIMM 102, which may be utilized in some embodiments. Without DIMM retention, DIMM 102 can fail operational vibration test (50 gram dummy card, e.g., in accordance with Intel® Blue Book board level vibe specification) with electric discontinuity occurring after about 1 micro second (us). A root cause may be significant DIMM lateral deflection during vibration.

Referring to FIG. 1, DIMM 102 can be any of a variety of types of DIMMs, such as an unbuffered or unregistered DIMM (UDIMM), a registered DIMM (RDIMM), a load reduced DIMM (LRDIMM), an enhanced load reduced DIMM (eLRDIMM), or other type of DIMM.

In one such example, the DIMM 102 and a DIMM connector are compatible with a memory standard such as a double data rate synchronous dynamic random-access memory (DDR) standard, including DDR3 (Double Data Rate version 3, released by JEDEC (Joint Electronic Device Engineering Council) on Jun. 27, 2007), DDR4 (DDR version 4, published in September 2012 by JEDEC), DDR5 (DDR version 5, published in July 2020), DDR6 (DDR version 6), LPDDR3 (Low Power DDR version 3, JESD209-3B, August 2013 by JEDEC), LPDDR4 (LPDDR version 4, JESD209-4, published by JEDEC in August 2014), LPDDR5 (LPDDR version 5, JESD209-5A, published by JEDEC in January 2020), or other memory technologies, including technologies based on derivatives or extensions of such specifications.

DIMM 102 includes DRAM chips 104 on both faces or sides of the DIMM 102. DIMM 102 includes additional circuitry 106 such as a registered or registering clock driver (RCD), data buffers, power management integrated circuit (PMIC), and/or other circuitry. DIMM 102 can be inserted or seated into the socket of a DIMM connector on a motherboard (not shown). The connector may include pins that make electrical and mechanical contact with contacts (e.g., gold fingers) 112A on the front side 110A (as well as the back side—not shown) of DIMM 102. The gold fingers 112A are coupled with the DRAM chips 104 on the DIMM via conductive traces on top of or embedded in the DIMM 102. In this way, signals are transmitted to and from the DRAM chips 104 via the connector.

DIMM 102 is a tall DIMM (e.g., taller than conventional DIMMs) and can be considered a 2U DIMM having a 2U height. A 2U DIMM has a module height that is greater than a standard 1U (“one unit”) DIMM, although embodiments are not limited to a 2U DIMM and even taller DIMMs may be utilized. In one embodiment, a 2U DIMM has at least twice the module height relative to a 1U DIMM. In another embodiment, a 2U DIMM has a maximum height of 58 mm. In an embodiment, the DIMM height is 58 mm. The 2U module height allows more DRAM chips 104 to be provided on each side of the DIMM 102. Although the greater height of the 2U DIMMs enables greater memory capacity, DIMMs that are significantly taller than conventional DIMMs have a heavier mass that increases the structural risk at the board and system level during shipping, handling, and in operation. In one example, compared to a standard 1U DDR DIMM, a 2U DIMM may nearly double the height of the center of gravity. With the increase in DIMM mass, the 2U DIMM shock and vibration risk increases and can potentially cause the 2U DIMMs to fail structural testing, e.g., fail operational vibration test (50 gram dummy card, e.g., in accordance with Intel® Blue Book board level vibe specification) with electric discontinuity occurring after about 1 micro second (us).

While some current solutions may provide board level mitigation without chassis attachment by using a DIMM connector retention with taller latch/constrain and/or screws, spacers, or DIMM tab features, these solutions are generally intended no to take any PCB real-estate. Such solutions may have need a new customized DIMM connector (which can be hard to implement by manufacturers) or they may have a high DIMM connector solder joint shock and vibration stress.

Also, at system level, some current mitigation designs may provide top retention to hold a DIMM's top edge which is generally attached to system chassis. With different chassis size, however, the attachment to top chassis needs to reach the chassis wall and may not be effective.

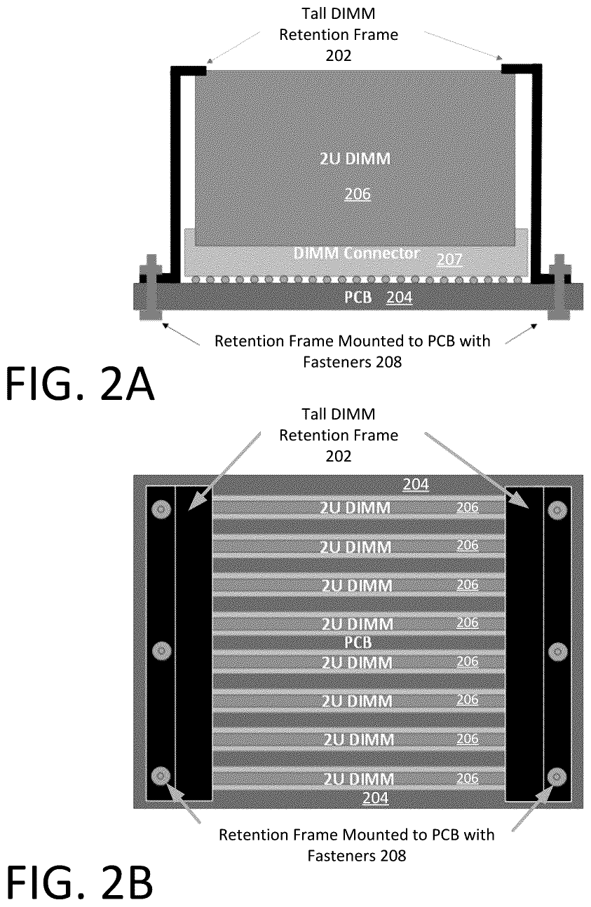

FIGS. 2A and 2B, respectively, illustrate a side view of a tall DIMM retention frame and a top view of the tall DIMM retention frame, according to some embodiments. The retention mechanism of FIGS. 2A and 2B constrain the top corners of the DIMM. A retention frame 202 is attached to a PCB 204 directly, as shown. The retention frame 202 constrains the top edges of the 2U DIMM 206. The DIMM 206 may be the same or similar to the DIMM 102 of FIG. 1. The DIMM 206 electrically couples with the PCB 204 via a DIMM connector 207. The DIMM connector 207 may be attached to the PCB 204 using various soldering techniques. The retention frame 202 is attached to the PCB 204 with fasteners 208.

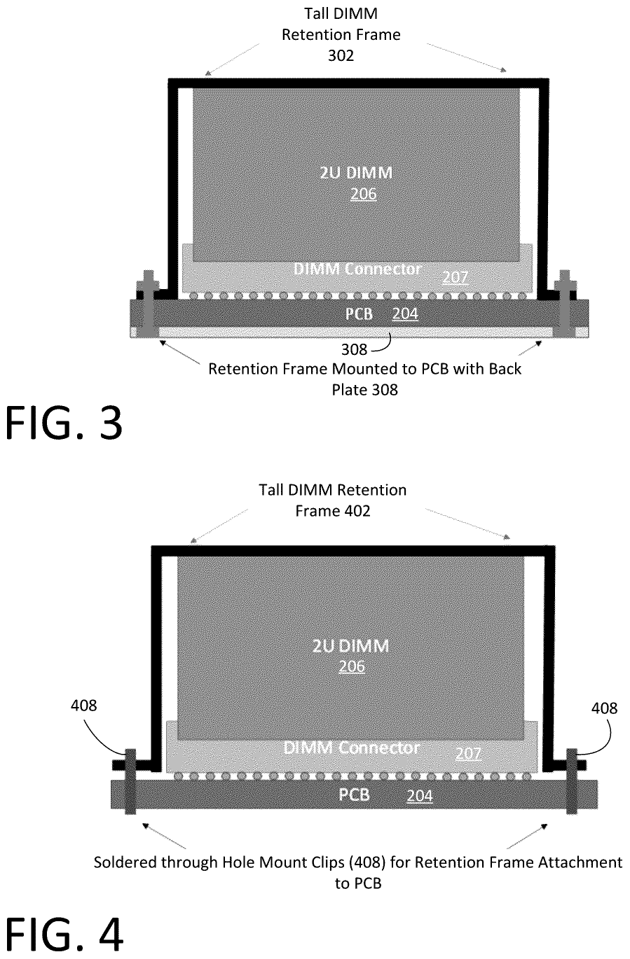

FIG. 3 illustrates a side view of a full DIMM retention frame 302 with a back plate attached to PCB, according to an embodiment. While retention frame 302 includes a contiguous top portion (e.g., to provide more rigidity and/or immersion cooling as further discussed herein), a non-contiguous retention frame such as shown in FIGS. 2A and 2B may also be used in some embodiments. The tall DIMM retention frame 302 is attached to the PCB 204 with a back plate 308, e.g., to provide a more rigid attachment and reduce movement in the z-direction (or vertical direction). The additional attachment support provided by the back plate 308 is envisioned to enhance structural rigidity and reduce lateral deflection/movement during vibration.

Also, while the back plate may provide mechanical support, in at least one embodiment, it may also be constructed to provide Electrical Magnetic Interference (EMI) protection (e.g., the back plate may be grounded, electrically conductive, etc.). In another embodiment, the back plate may also be part of a cooling, thermal solution (e.g., to provide air and/or immersion cooling). In various embodiments, the back plate 308 may be constructed with copper, aluminum, or combinations thereof.

FIG. 4 illustrates a side view of a full DIMM retention frame 402 attached to hole mount clips on a motherboard, according to an embodiment. In an embodiment, Plated-Through-Hole (PTH) clips (and/or soldered through hole mount clips) 408 may be utilized to attach the frame 402 to the PCB 204.

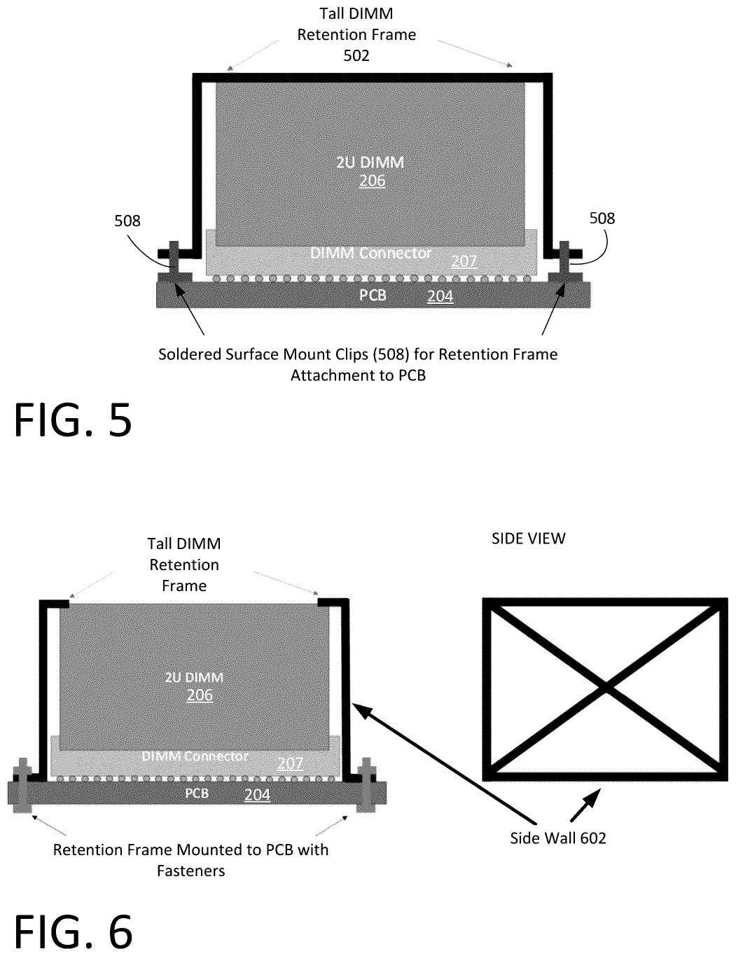

FIG. 5 illustrates a side view of a full DIMM retention frame 502 attached to soldered surface mount clips or hooks on a motherboard, according to an embodiment. In an embodiment, Surface Mount Technology (SMT) clips/hooks 508 may be utilized to attach the frame 502 to the PCB 204.

FIGS. 3, 4, and 5 show a one-piece full frame design for retention frames 302, 402, and 502, which constrain the entire top edge of a DIMM.

FIG. 6 shows a side view of a tall DIMM retention frame 602, according to an embodiment. The openings in the side wall 602 allow for enhanced air flow (e.g., for cooling), while achieving structural stiffness. While some embodiments (such as FIGS. 6 and 8) illustrate a cross structure for at least a portion of the DIMM retention frames, embodiments are not limited to this and any shaped cutout may be utilized.

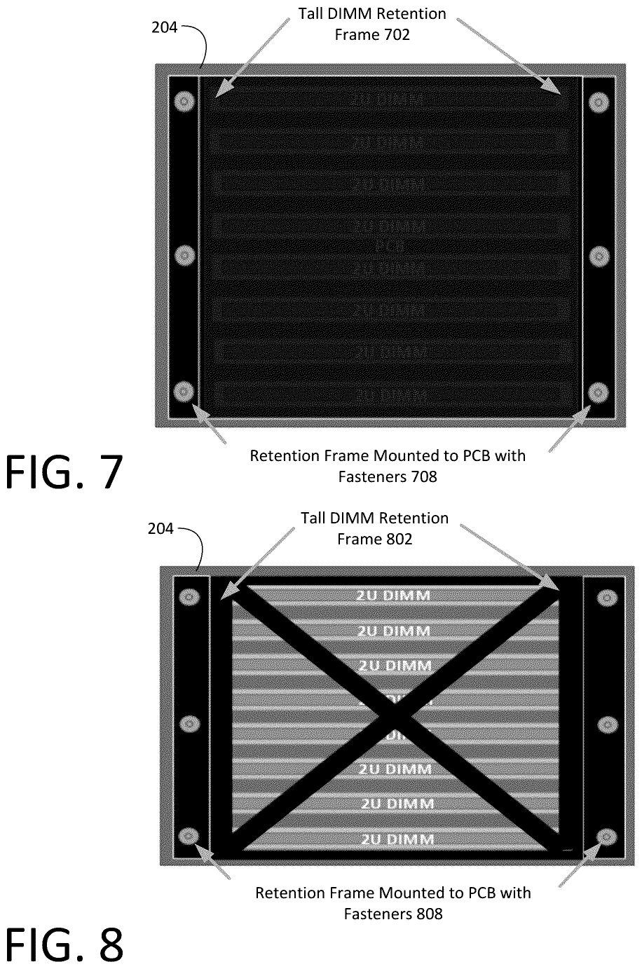

FIG. 7 illustrates a top view of a full tall DIMM retention frame 702 constraining DIMM top edge, according to an embodiment. The full retention frame 702 provides for additional rigidity when compared to a partial retention frame such as those shown in FIGS. 2A, 2B, 5, and/or 6 for example. The full retention frame 702 is attached to the PCB 204 via fasteners 708). The fasteners discussed herein may include any type of device capable of physically attaching two objects, including, for example, a soldered through hole mount clip, a threaded screw, a thumb screw, a Plated-Through-Hole (PTH) clip, a Surface Mount Technology (SMT) clip or hook, a locking tab, a locking pen, etc. Moreover, the full/solid retention frame may include one or more internal passages to allow for liquid flow to provide enhanced immersion cooling, while the partial retention frame may include one or more cutouts to allow for air flow to provide enhanced air cooling.

FIG. 8 illustrates a top view of a partial tall DIMM retention frame 802, according to an embodiment. The retention frame 802 includes cutouts to reduce frame mass, while achieving frame structural stiffness. As mentioned before, the cutouts in any portion of the DIMM retention frames discussed herein may also provide better air flow for cooling.

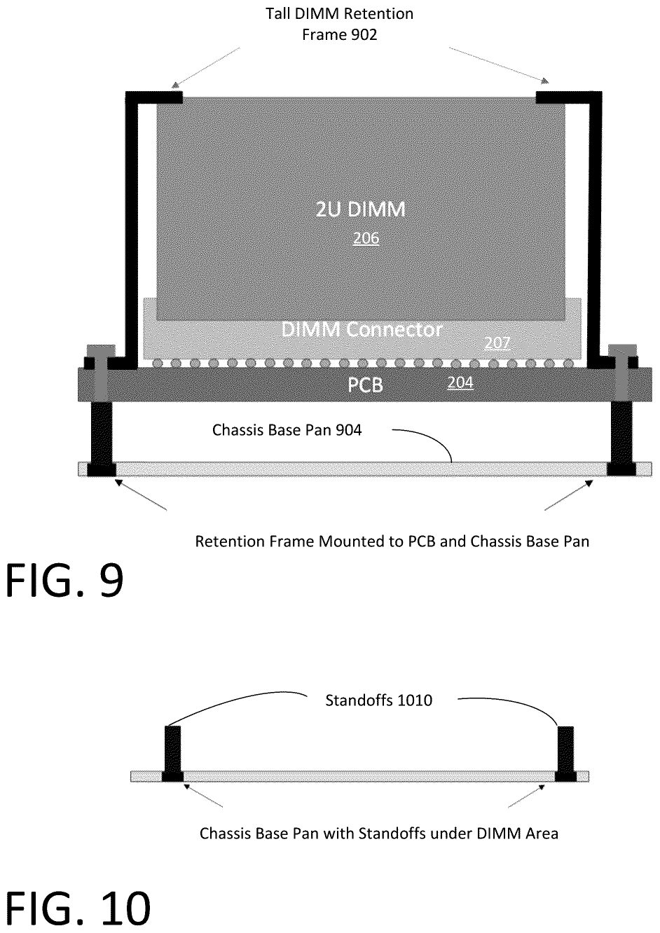

Some embodiments utilize tall DIMMs direct chassis backside attach, as further discussed with reference to FIGS. 9 to 12 below. Moreover, on the top side, the retention frames constrain the top corners and/or edge of DIMMs and prevent tall DIMM lateral movement. On the bottom side, the retention frames may be attached to the chassis through the PCB, e.g., to prevent or reduce movement along the z-direction (or vertical) for the whole DIMM/connector/PCB module assembly.

FIG. 9 illustrates a side view of a partial tall DIMM retention frame 902, according to an embodiment. The retention frame 902 constrains the top corners of the DIMM 206 and is attached to the PCB 204 and a chassis base pan 904, using any of the fasteners types discussed herein.

FIG. 10 illustrates an exploded view of a portion of the DIMM retention frame mount of FIG. 9, according to an embodiment. FIG. 10 shows the chassis base pan 904 with motherboard standoffs 1010. The standoffs 1010 may provide a gap between the chassis base pan and the PCB for electrical isolation and/or insulation. The standoffs 1010 may provide enhanced air flow for air cooling by providing a gap between the chassis base pan and the PCB. Referring to FIGS. 9-10, the PCB 204 with DIMM modules 206 and the retention frame 902 are mounted to the standoffs 1010 with screws (or other types of fasteners discussed herein).

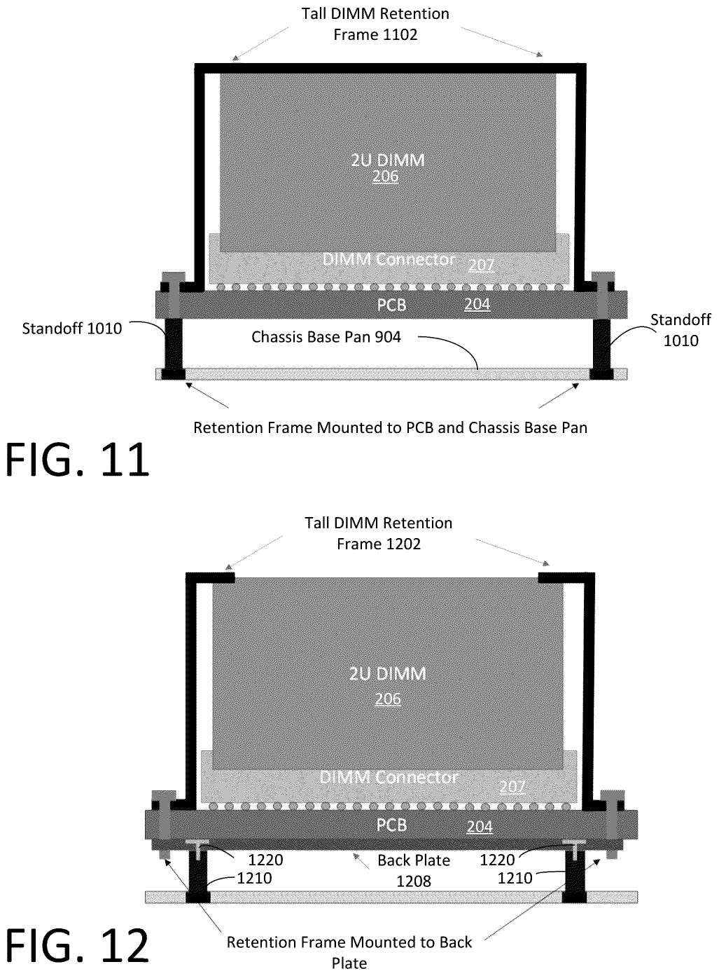

FIG. 11 illustrates a one-piece or full tall DIMM retention frame 1102, according to an embodiment. The Tall DIMM retention frame 1102 is mounted using the direct chassis attach technique, such as discussed with reference to FIGS. 9-10.

FIG. 12 illustrates a side view of a partial DIMM retention frame 1202, according to an embodiment. The tall DIMM retention frame 1202 is attached using the direct chassis attach technique (such as discussed with reference to FIGS. 9-11), with the addition of a back plate 1208. The back plate 1208 may be the same or similar to the back plate 308 of FIG. 3.

As shown, the back plate 1208 is attached or mounted to the standoffs 1210 (which may be the same as or similar to standoffs 1010) and the retention frame 1202 is attached to the back plate 1208.

In an embodiment, stud inserts or thread studs 1220 provide a feature for the mounting hardware to align the back plate 1208 and the standoffs 1210 for a flush attachment.

Hence, some embodiments (such as those discussed with reference to FIGS. 9-12) can constrain both the 2U DIMMs and PCB against shock and/or vibration risk. Such embodiments may mitigate DIMM lateral movement and/or mitigate movement in the z-axis (or vertical direction) for DIMM module, connector, and/or PCB.

Furthermore, one or more embodiments (such as those shown in FIGS. 2 et seq.) are envisioned to: (a) reduce DIMM connector solder joint failure risk significantly by providing a compressive joint force; and/or (b) reduce tall DIMM lateral deflection significantly by providing effective retention through motherboard and/or chassis pan attachment.

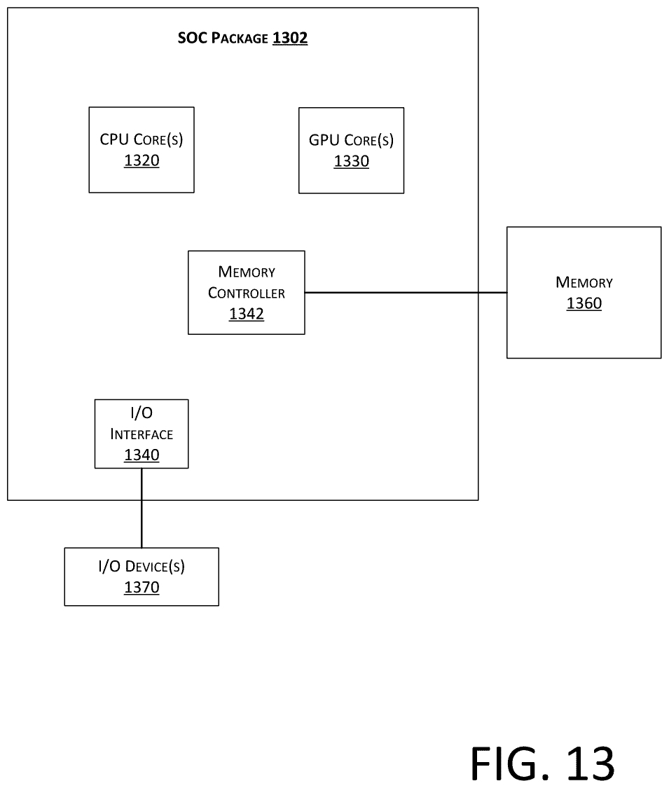

One or more components discussed with reference to FIGS. 13-15 (including but not limited to I/O devices, memory/storage devices, graphics/processing cards/devices, network/bus/audio/display/graphics controllers, wireless transceivers, etc.) may be protected from solder joint failure and/or lateral deflection by utilizing the techniques and/or retention structures discussed above with reference to FIGS. 1-12. More particularly, FIG. 13 illustrates a block diagram of a System on Chip (“SOC” or “SoC”) package in accordance with an embodiment. As illustrated in FIG. 13, SOC 1302 includes one or more Central Processing Unit (CPU) or processor cores 1320, one or more Graphics Processor Unit (GPU) cores 1330, an Input/Output (I/O) interface 1340, and a memory controller 1342. Various components of the SOC package 1302 may be coupled to an interconnect or bus such as discussed herein with reference to the other figures. Also, the SOC package 1302 may include more or less components, such as those discussed herein with reference to the other figures. Further, each component of the SOC package 1320 may include one or more other components, e.g., as discussed with reference to the other figures herein. In one embodiment, SOC package 1302 (and its components) is provided on one or more Integrated Circuit (IC) die, e.g., which are packaged into a single semiconductor device.

As illustrated in FIG. 13, SOC package 1302 is coupled to a memory 1360 via the memory controller 1342. In an embodiment, the memory 1360 (or a portion of it) can be integrated on the SOC package 1302.

The I/O interface 1340 may be coupled to one or more I/O devices 1370, e.g., via an interconnect and/or bus such as discussed herein with reference to other figures. I/O device(s) 1370 may include one or more of a keyboard, a mouse, a touchpad, a display, an image/video capture device (such as a camera or camcorder/video recorder), a touch screen, a speaker, or the like.

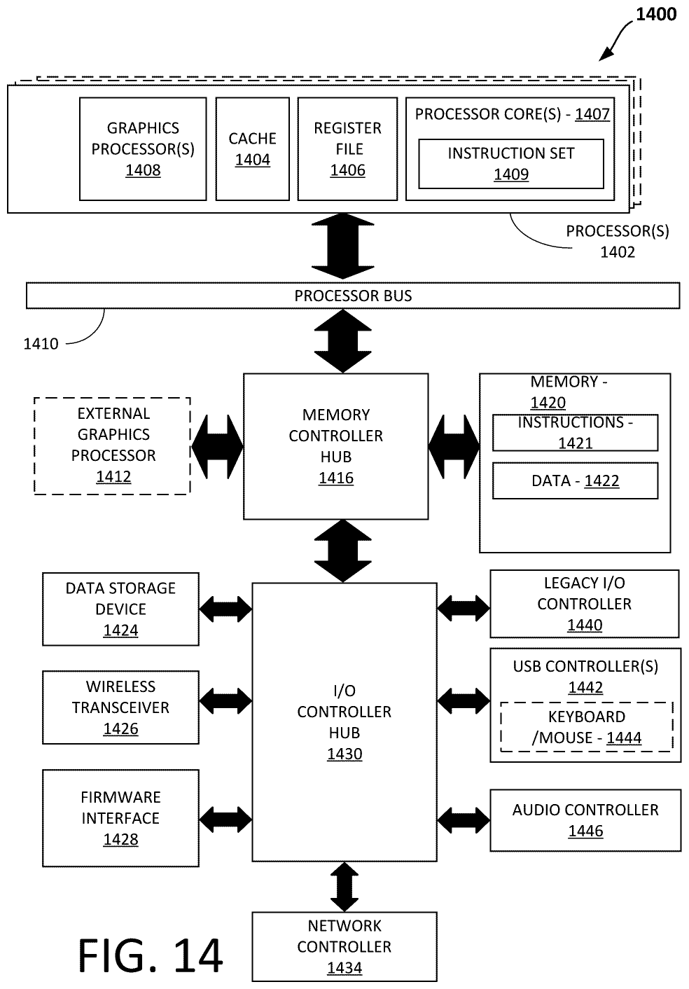

FIG. 14 is a block diagram of a processing system 1400, according to an embodiment. In various embodiments the system 1400 includes one or more processors 1402 and one or more graphics processors 1408, and may be a single processor desktop system, a multiprocessor workstation system, or a server system having a large number of processors 1402 or processor cores 1407. In an embodiment, the system 1400 is a processing platform incorporated within a system-on-a-chip (SoC or SOC) integrated circuit for use in mobile, handheld, or embedded devices.

An embodiment of system 1400 can include, or be incorporated within a server-based gaming platform, a game console, including a game and media console, a mobile gaming console, a handheld game console, or an online game console. In some embodiments system 1400 is a mobile phone, smart phone, tablet computing device or mobile Internet device. Data processing system 1400 can also include, couple with, or be integrated within a wearable device, such as a smart watch wearable device, smart eyewear device, augmented reality device, or virtual reality device. In some embodiments, data processing system 1400 is a television or set top box device having one or more processors 1402 and a graphical interface generated by one or more graphics processors 1408.

In some embodiments, the one or more processors 1402 each include one or more processor cores 1407 to process instructions which, when executed, perform operations for system and user software. In some embodiments, each of the one or more processor cores 1407 is configured to process a specific instruction set 1409. In some embodiments, instruction set 1409 may facilitate Complex Instruction Set Computing (CISC), Reduced Instruction Set Computing (RISC), or computing via a Very Long Instruction Word (VLIW). Multiple processor cores 1407 may each process a different instruction set 1409, which may include instructions to facilitate the emulation of other instruction sets. Processor core 1407 may also include other processing devices, such a Digital Signal Processor (DSP).

In some embodiments, the processor 1402 includes cache memory 1404. Depending on the architecture, the processor 1402 can have a single internal cache or multiple levels of internal cache. In some embodiments, the cache memory is shared among various components of the processor 1402. In some embodiments, the processor 1402 also uses an external cache (e.g., a Level-3 (L3) cache or Last Level Cache (LLC)) (not shown), which may be shared among processor cores 1407 using known cache coherency techniques. A register file 1406 is additionally included in processor 1402 which may include different types of registers for storing different types of data (e.g., integer registers, floating point registers, status registers, and an instruction pointer register). Some registers may be general-purpose registers, while other registers may be specific to the design of the processor 1402.

In some embodiments, processor 1402 is coupled to a processor bus 1410 to transmit communication signals such as address, data, or control signals between processor 1402 and other components in system 1400. In one embodiment the system 1400 uses an exemplary ‘hub’ system architecture, including a memory controller hub 1416 and an Input Output (I/O) controller hub 1430. A memory controller hub 1416 facilitates communication between a memory device and other components of system 1400, while an I/O Controller Hub (ICH) 1430 provides connections to I/O devices via a local I/O bus. In one embodiment, the logic of the memory controller hub 1416 is integrated within the processor.

Memory device 1420 can be a dynamic random access memory (DRAM) device, a static random access memory (SRAM) device, flash memory device, phase-change memory device, or some other memory device having suitable performance to serve as process memory. In one embodiment the memory device 1420 can operate as system memory for the system 1400, to store data 1422 and instructions 1421 for use when the one or more processors 1402 executes an application or process. Memory controller hub 1416 also couples with an optional external graphics processor 1412, which may communicate with the one or more graphics processors 1408 in processors 1402 to perform graphics and media operations.

In some embodiments, ICH 1430 enables peripherals to connect to memory device 1420 and processor 1402 via a high-speed I/O bus. The I/O peripherals include, but are not limited to, an audio controller 1446, a firmware interface 1428, a wireless transceiver 1426 (e.g., Wi-Fi, Bluetooth), a data storage device 1424 (e.g., hard disk drive, flash memory, etc.), and a legacy I/O controller 1440 for coupling legacy (e.g., Personal System 2 (PS/2)) devices to the system. One or more Universal Serial Bus (USB) controllers 1442 connect input devices, such as keyboard and mouse 1444 combinations. A network controller 1434 may also couple to ICH 1430. In some embodiments, a high-performance network controller (not shown) couples to processor bus 1410. It will be appreciated that the system 1400 shown is exemplary and not limiting, as other types of data processing systems that are differently configured may also be used. For example, the I/O controller hub 1430 may be integrated within the one or more processor 1402, or the memory controller hub 1416 and I/O controller hub 1430 may be integrated into a discreet external graphics processor, such as the external graphics processor 1412.

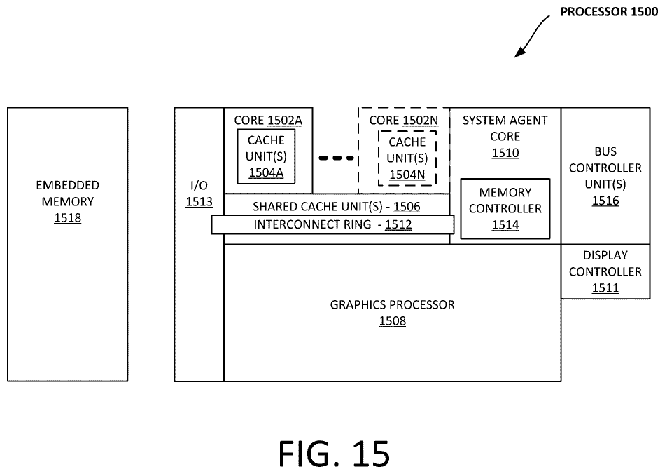

FIG. 15 is a block diagram of an embodiment of a processor 1500 having one or more processor cores 1502A to 1502N, an integrated memory controller 1514, and an integrated graphics processor 1508. Those elements of FIG. 15 having the same reference numbers (or names) as the elements of any other figure herein can operate or function in any manner similar to that described elsewhere herein, but are not limited to such. Processor 1500 can include additional cores up to and including additional core 1502N represented by the dashed lined boxes. Each of processor cores 1502A to 1502N includes one or more internal cache units 1504A to 1504N. In some embodiments each processor core also has access to one or more shared cached units 1506.

The internal cache units 1504A to 1504N and shared cache units 1506 represent a cache memory hierarchy within the processor 1500. The cache memory hierarchy may include at least one level of instruction and data cache within each processor core and one or more levels of shared mid-level cache, such as a Level 2 (L2), Level 3 (L3), Level 4 (L4), or other levels of cache, where the highest level of cache before external memory is classified as the LLC. In some embodiments, cache coherency logic maintains coherency between the various cache units 1506 and 1504A to 1504N.

In some embodiments, processor 1500 may also include a set of one or more bus controller units 1516 and a system agent core 1510. The one or more bus controller units 1516 manage a set of peripheral buses, such as one or more Peripheral Component Interconnect buses (e.g., PCI, PCI Express). System agent core 1510 provides management functionality for the various processor components. In some embodiments, system agent core 1510 includes one or more integrated memory controllers 1514 to manage access to various external memory devices (not shown).

In some embodiments, one or more of the processor cores 1502A to 1502N include support for simultaneous multi-threading. In such embodiment, the system agent core 1510 includes components for coordinating and operating cores 1502A to 1502N during multi-threaded processing. System agent core 1510 may additionally include a power control unit (PCU), which includes logic and components to regulate the power state of processor cores 1502A to 1502N and graphics processor 1508.

In some embodiments, processor 1500 additionally includes graphics processor 1508 to execute graphics processing operations. In some embodiments, the graphics processor 1508 couples with the set of shared cache units 1506, and the system agent core 1510, including the one or more integrated memory controllers 1514. In some embodiments, a display controller 1511 is coupled with the graphics processor 1508 to drive graphics processor output to one or more coupled displays. In some embodiments, display controller 1511 may be a separate module coupled with the graphics processor via at least one interconnect, or may be integrated within the graphics processor 1508 or system agent core 1510.

In some embodiments, a ring-based interconnect unit 1512 is used to couple the internal components of the processor 1500. However, an alternative interconnect unit may be used, such as a point-to-point interconnect, a switched interconnect, or other techniques, including techniques well known in the art. In some embodiments, graphics processor 1508 couples with the ring interconnect 1512 via an I/O link 1513.

The exemplary I/O link 1513 represents at least one of multiple varieties of I/O interconnects, including an on package I/O interconnect which facilitates communication between various processor components and a high-performance embedded memory module 1518, such as an eDRAM (or embedded DRAM) module. In some embodiments, each of the processor cores 1502 to 1502N and graphics processor 1508 use embedded memory modules 1518 as a shared Last Level Cache.

In some embodiments, processor cores 1502A to 1502N are homogenous cores executing the same instruction set architecture. In another embodiment, processor cores 1502A to 1502N are heterogeneous in terms of instruction set architecture (ISA), where one or more of processor cores 1502A to 1502N execute a first instruction set, while at least one of the other cores executes a subset of the first instruction set or a different instruction set. In one embodiment processor cores 1502A to 1502N are heterogeneous in terms of microarchitecture, where one or more cores having a relatively higher power consumption couple with one or more power cores having a lower power consumption. Additionally, processor 1500 can be implemented on one or more chips or as an SoC integrated circuit having the illustrated components, in addition to other components.

The following examples pertain to further embodiments. Example 1 includes an apparatus comprising: a Dual In-Line Memory Module (DIMM) retention frame coupled to a top portion of a tall DIMM; and a plurality of fasteners to physically attach the DIMM retention frame to a Printed Circuit Board (PCB), wherein the DIMM retention frame is to reduce movement of the tall DIMM. Example 2 includes the apparatus of example 1, wherein the top portion of the tall DIMM comprises at least two top corners of the tall DIMM. Example 3 includes the apparatus of example 1, wherein the top portion of the tall DIMM comprises the entire top edge of the tall DIMM. Example 4 includes the apparatus of example 1, wherein the plurality of fasteners comprise at least one of: a soldered through hole mount clip, a threaded screw, a thumb screw, a Plated-Through-Hole (PTH) clip, a Surface Mount Technology (SMT) clip or hook, a locking tab, and a locking pen.

Example 5 includes the apparatus of example 1, wherein a side wall of the DIMM retention frame is solid. Example 6 includes the apparatus of example 5, wherein the solid side wall comprises one or more internal passages to allow for liquid flow to provide immersion cooling. Example 7 includes the apparatus of example 1, wherein a side wall of the DIMM retention frame comprises one or more cutouts. Example 8 includes the apparatus of example 7, wherein the one or more cutouts are to allow for air flow to provide air cooling. Example 9 includes the apparatus of example 1, wherein a top surface of the DIMM retention frame, adjacent to the tope edge of the tall DIMM, is solid.

Example 10 includes the apparatus of example 9, wherein the top surface of the DIMM retention frame comprises one or more internal passages to allow for liquid flow to provide immersion cooling. Example 11 includes the apparatus of example 1, wherein a top surface of the DIMM retention frame, adjacent to the tope edge of the tall DIMM, comprises one or more cutouts. Example 12 includes the apparatus of example 11, wherein the one or more cutouts are to allow for air flow to provide air cooling. Example 13 includes the apparatus of example 1, wherein the DIMM retention frame is coupled to a top side of the PCB, wherein the plurality of fasteners are to physically attach the DIMM retention frame to a back plate disposed on a bottom side of the PCB.

Example 14 includes the apparatus of example 1, wherein the DIMM retention frame is coupled to a chassis base pan through the PCB. Example 15 includes the apparatus of example 14, further comprising a plurality of standoffs coupled between the chassis base pan and the PCB. Example 16 includes the apparatus of example 15, further comprising a plurality of studs to provide a feature to align a back plate and the plurality of standoffs. Example 17 includes the apparatus of example 16, wherein the DIMM retention frame is coupled to a top side of the PCB, wherein the plurality of fasteners are to physically attach the DIMM retention frame to the back plate disposed on a bottom side of the PCB.

Example 18 includes a system comprising: a processor to execute one or more instructions; a tall Dual In-Line Memory Module (DIMM), coupled to the processor, to store data to be processed by the processor; a DIMM retention frame coupled to a top portion of the tall DIMM; and a plurality of fasteners to physically attach the DIMM retention frame to a Printed Circuit Board (PCB), wherein the DIMM retention frame is to reduce movement of the tall DIMM. Example 19 includes the system of example 18, wherein the DIMM retention frame is coupled to a top side of the PCB, wherein the plurality of fasteners are to physically attach the DIMM retention frame to a back plate disposed on a bottom side of the PCB. Example 20 includes the system of example 18, wherein the DIMM retention frame is coupled to a chassis base pan through the PCB.

Example 21 includes an apparatus comprising means to perform a method as set forth in any preceding example.

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
a Dual In-Line Memory Module (DIMM) retention frame coupled to a top portion of a tall DIMM; and
a plurality of fasteners to physically attach the DIMM retention frame to a Printed Circuit Board (PCB),
wherein the DIMM retention frame is to reduce movement of the tall DIMM.

2. The apparatus of claim 1, wherein the top portion of the tall DIMM comprises at least two top corners of the tall DIMM.

3. The apparatus of claim 1, wherein the top portion of the tall DIMM comprises the entire top edge of the tall DIMM.

4. The apparatus of claim 1, wherein the plurality of fasteners comprise at least one of: a soldered through hole mount clip, a threaded screw, a thumb screw, a Plated-Through-Hole (PTH) clip, a Surface Mount Technology (SMT) clip or hook, a locking tab, and a locking pen.

5. The apparatus of claim 1, wherein a side wall of the DIMM retention frame is solid.

6. The apparatus of claim 5, wherein the solid side wall comprises one or more internal passages to allow for liquid flow to provide immersion cooling.

7. The apparatus of claim 1, wherein a side wall of the DIMM retention frame comprises one or more cutouts.

8. The apparatus of claim 7, wherein the one or more cutouts are to allow for air flow to provide air cooling.

9. The apparatus of claim 1, wherein a top surface of the DIMM retention frame, adjacent to the tope edge of the tall DIMM, is solid.

10. The apparatus of claim 9, wherein the top surface of the DIMM retention frame comprises one or more internal passages to allow for liquid flow to provide immersion cooling.

11. The apparatus of claim 1, wherein a top surface of the DIMM retention frame, adjacent to the tope edge of the tall DIMM, comprises one or more cutouts.

12. The apparatus of claim 11, wherein the one or more cutouts are to allow for air flow to provide air cooling.

13. The apparatus of claim 1, wherein the DIMM retention frame is coupled to a top side of the PCB, wherein the plurality of fasteners are to physically attach the DIMM retention frame to a back plate disposed on a bottom side of the PCB.

14. The apparatus of claim 1, wherein the DIMM retention frame is coupled to a chassis base pan through the PCB.

15. The apparatus of claim 14, further comprising a plurality of standoffs coupled between the chassis base pan and the PCB.

16. The apparatus of claim 15, further comprising a plurality of studs to provide a feature to align a back plate and the plurality of standoffs.

17. The apparatus of claim 16, wherein the DIMM retention frame is coupled to a top side of the PCB, wherein the plurality of fasteners are to physically attach the DIMM retention frame to the back plate disposed on a bottom side of the PCB.

18. A system comprising:
a processor to execute one or more instructions;
a tall Dual In-Line Memory Module (DIMM), coupled to the processor, to store data to be processed by the processor;
a DIMM retention frame coupled to a top portion of the tall DIMM; and
a plurality of fasteners to physically attach the DIMM retention frame to a Printed Circuit Board (PCB),
wherein the DIMM retention frame is to reduce movement of the tall DIMM.

19. The system of claim 18, wherein the DIMM retention frame is coupled to a top side of the PCB, wherein the plurality of fasteners are to physically attach the DIMM retention frame to a back plate disposed on a bottom side of the PCB.

20. The system of claim 18, wherein the DIMM retention frame is coupled to a chassis base pan through the PCB.
